(19) United States
(12) Patent Application Publication
(10) Pub. No.: US 2017/0359057 A1
(43) Pub. Date: Dec. 14, 2017

(54) Methods and Apparatus for Synchronized Control of Multi-Channel Load Switches

(71) Applicant: GLF INTEGRATED POWER INC., a Delaware corporation, Fremont, CA (US)

(72) Inventors: Stephen W. Bryson, Cupertino, CA (US); Ni Sun, Sunnyvale, CA (US)

(73) Assignee: GLF INTEGRATED POWER INC., a Delaware corporation, Fremont, CA (US)

(21) Appl. No.: 15/669,690

(22) Filed: Aug. 4, 2017

Related U.S. Application Data
(63) Continuation-in-part of application No. 14/586,586, filed on Dec. 30, 2014.
Application No. 14/586,586 is a continuation-in-part of application No. 14/638,989, filed on Mar. 4, 2015.
Application No. 14/638,989 is a continuation-in-part of application No. 14/469,270, filed on Aug. 26, 2014, now Pat. No. 9,647,657.
(60) Provisional application No. 62/478,607, filed on Mar. 30, 2017.

(51) Int. Cl. H03K 17/16; H02H 5/04; H02H 3/18; H02H 3/24; H02J 7/34

(52) U.S. Cl. CPC H03K 17/161; H02H 3/243; H02J 7/345; H02H 3/18; H02H 5/04

(57) ABSTRACT

Described are apparatus and methods for control of multi-channel load switches with synchronized power up/down timing sequences. The slew rate control methods of the PMOS load switches contained in the N Multi-channel configuration is also described. A preferred slew rate control circuit includes a power PMOS transistor that is capable of handling load currents of several amperes along with an integrated controller. The integrated controller allows the user to program the power on/off sequences of each of the load switch channels by simply using a single or multiple input enable input pins.

### BACKGROUND OF THE INVENTION

### 1. Field of the Invention

Described herein are apparatus and methods for synchronized control of N Multi-channel load switches. These techniques allow for multiple channels that are connected to different power rails to be sequenced in the correct order such that the application subsystems utilizing those power rails would be brought up in the proper sequence and can be powered down with a different sequence.

### 2. Description of the Related Art

This application is a continuation-in-part (CIP) application of prior application Ser. No. 14/469,270 filed on 2014 Aug. 26, a continuation-in-part (CIP) application of prior application Ser. No. 14/586,586 filed on 2014 Dec. 30, and a continuation-in-part (CIP) application of prior application Ser. No. 14/638,989 filed on 2015 Mar. 4. Present application seeks the same priority as that of these applications. And this application is a non-provisional application of the provisional application with Application No. 62/478,607 filed on 2017 Mar. 30. The entire contents of each of which are incorporated herein by reference.

### BRIEF SUMMARY OF THE PRESENT INVENTION

Over the last decade the proliferation of mobile devices has mushroomed. From the creation of the portable digital assistant (PDA) to the development of smart phones, the need for consumers to have more computing power on the go has risen dramatically. The recent development of smart watches has extended that development into even smaller form factors requiring the equivalent computing power of a smart phone but with extended battery life. These new smart watches can be used to connect to a variety of external systems with Bluetooth, text message, or GPS tracking. All of these subsystems need to be managed properly and turned on and off appropriately with the application processor.

Into this environment has emerged the load switch; a smart version of the Power MOSFET. These load switched can be used to completely remove the power from various subsystems with extremely low leakage currents extending the life of the small watch batteries. However, using multiple independent load switches that are connected to the various subsystems uses valuable board real estate in a smart watch, not to mention the control circuitry needed to synchronize the systems for the proper power up/down sequencing. Furthermore, these different subsystems have different current requirements as well as different turn on/off times. This can cause the smart watch manufacturer to have to have large inventories of several different load switch types possibly from different vendors.

Entering into this design challenge comes the N Multi-channel load switch with individual power up/down sequencing. Depending upon the requirements, these unique monolithic integrated circuits can contain two, three, or even four uniquely controllable load switch devices which can be controlled individually or synchronously with a single enable pin. In the simplest configuration, the N Multi-channel load switch could have two control pins and an on board decoder that would allow up to 4 load switches to be controlled. This architecture would require the application processor to keep track of the timing sequence of each load switch and issue the appropriate combination of enable signals to the multi-channel load switch at the appropriate time, similar to how one would control a group of individual load switch ICs. This architecture allows for the most flexible design options, however, it burdens the application processor timing circuits to produce the appropriate power up/down timing for each load switch channel. An alternative approach unburdens the processor with the timing requirements and allows the multi-channel load switch to take control of the individual load switch channel timing. In this architecture the timing circuits are off loaded to the load switch IC allowing it autonomous control of the various channels. All the processor has to do is issue a single enable or disable command and the load switch IC will perform the power up/down functions with the appropriate timing for each channel.

### BRIEF DESCRIPTION OF THE DRAWINGS

FIG. 1 shows the overall block diagram of general switching circuit (SC) 100 with a synchronization control circuit (SCC) 140.

FIG. 2 is a simplified schematic of a single channel of the multi-channel load switches.

FIG. 3 shows an alternative embodiment of a single channel that can be used as one of the channels on a Multi-channel load switches.

FIG. 4 illustrates an alternative embodiment of a single channel within the N Multi-channel load switches architecture.

FIG. 5 shows how a typical N Multi-channel load switch timing synchronization might work.

FIG. 6 illustrates an embodiment of the N Multi-channel load switch consisting of 4 independent load switches (LS_i) 10i with the synchronization control circuit (SCC) 140.

FIG. 7 shows an embodiment of the 4 channel load switches with two enable input pins allowing for an independent selection version of 1 out of 4 input voltages.

FIG. 8 illustrates the configuration of ON/OFF-timing circuits (OTC_i) 81i within a synchronization control circuit.

FIG. 9 shows a block diagram of the synchronization and control block for a single channel of the N Multi-channel load switches.

FIG. 10 shows the architecture of ON/OFF delay circuit that is used in both the ON and OFF delay functions in the synchronization control circuit (SCC) 140.

FIG. 11 illustrates an embodiment of the ON/OFF-timing circuits (OTC_i) 81i using a voltage control oscillator (VCO) 111i/112i.

### DETAILED DESCRIPTION OF THE INVENTION

The following description with reference to exemplary and illustration drawings of the present invention will be further described in detail, but the present illustration is not intended to limit the embodiment of the present invention, any similar structure of the present invention and similar changes should be included in the scope of the present invention.

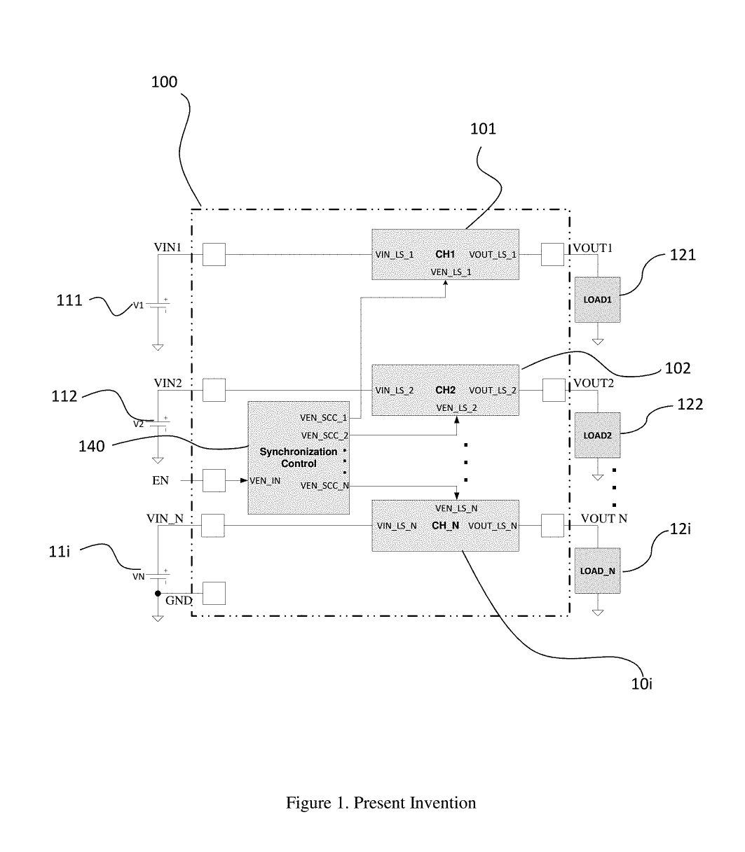

Below in conjunction with illustration with the FIGS. 1-11, the present invention will be described in detail as follows.

As shown in the FIG. 1, the present invention is about a switching circuit (SC) 100 and method of making it that can be connected between external input voltage sources 11i and external output loads 12i, including at least two or more load switches (LS_i) 10i in combination with a synchronization control circuit (SCC) 140 for providing power up/down sequencing for the load switches (LS_i) 10i, wherein i represents any integer larger than 0. There are multiple load switches (LS_i) 10i, the object of the load switches (LS_i) 10i is to protect the load devices 12i from any possible overvoltage condition due to a possible inrush current that can be present when connecting the load devices 12i to the input voltage sources 11i.

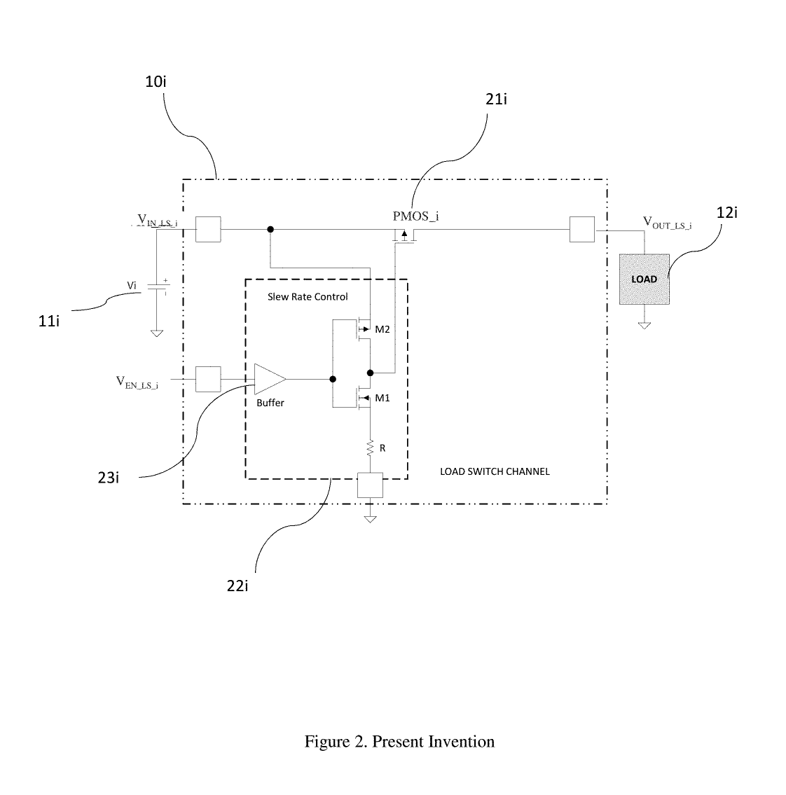

Each load switch (LS_i) 10i is connected between an input voltage source 11i on the V_{IN}_{_}_{LS}_{_}ᵢ pin to the output load devices on the V_{OUT}_{_}_{LS}_{_}ᵢ pin. As shown in the FIG. 2, each load switch (LS_i) 10i has:
a. a PMOS transistor (PMOS_i) 21i with its source and drain respectively connected to the power input V_{IN}_{_}_{LS}_{_}ᵢ and the power output V_{OUT}_{_}_{LS}_{_}ᵢ; and
b. a slew rate control circuit (SRCC_i) 22i with its input connected to the output V_{EN}_{_}_{SCC}_{_}_{OUT}_{_}ᵢ of the synchronization control circuit (SCC) 140 and having its output connected the gate of the PMOS transistor (PMOS_i) 21i.

Each PMOS transistor (PMOS_i) 21i is connected input voltage sources 11i such as a battery or voltage source created by a voltage regulator circuit and an output load device 12i. Also included is the slew rate control circuit (SRCC_i) 22i that is connected to the gate of the PMOS transistor (PMOS_i) 21i, which when turned on will cause the turn on of the power PMOS transistor (PMOS_i) 21i and the transition of the voltage at the output of the switch from zero volts to the V_{IN}_{_}_{LS}_{_}ᵢ voltage, minus a small voltage drop due to the R_{DSON} of the PMOS transistor (PMOS_i) 21i. And when turned off, the slew rate control circuit (SRCC_i) 22i will become disabled, thereby saving power during the time that the PMOS transistor (PMOS_i) 21i are in the OFF position.

The slew rate control circuit (SRCC_i) 22i can take on many forms to produce the overall result. In the embodiment shown in the FIG. 2, the load switch (LS_i) 10i consists of an input buffer 23i that is connected to the V_{EN}_{_}_{LS}_{_}ᵢ input. The output of the buffer 23i is then connected to an inverter stage that consists of a PMOS pull up transistor labeled M2 and a NMOS pull down transistor labeled M1. In order to control the slew rate of the gate voltage of the PMOS load switch transistor, a resistor is placed in the source of the NMOS pull down transistor. Thus the current generated to pull down the gate voltage of the PMOS load switch will be:

I_{DSCG}=(V_{GATE}−V_{DS(M1)})/R (1)

The rate at which the gate of the PMOS load switch is discharged can be calculated by using the equation:

Discharge Time=C_{GATE}*VIN/I_{DSCG} (2)

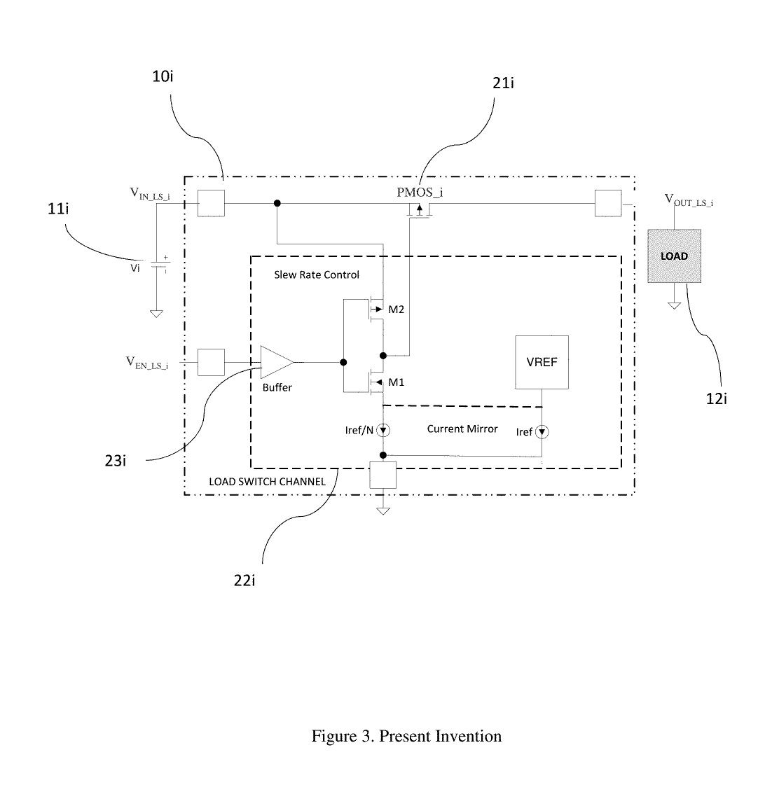

Another embodiment of the slew rate control circuit (SRCC_i) 22i is illustrate in the FIG. 3. The resistor is replaced by a current mirror which obtains a reference current from a stable voltage source such as a band gap reference circuit. The current mirror is then use to divide the reference current by a dividing ratio N in order to obtain the desired I_{DSCG} current. This technique is used when the turn on time of the power PMOS transistor (PMOS_i) 201 needs to be extended beyond 1-2 ms, which is the practical limit for a resistor based solution.

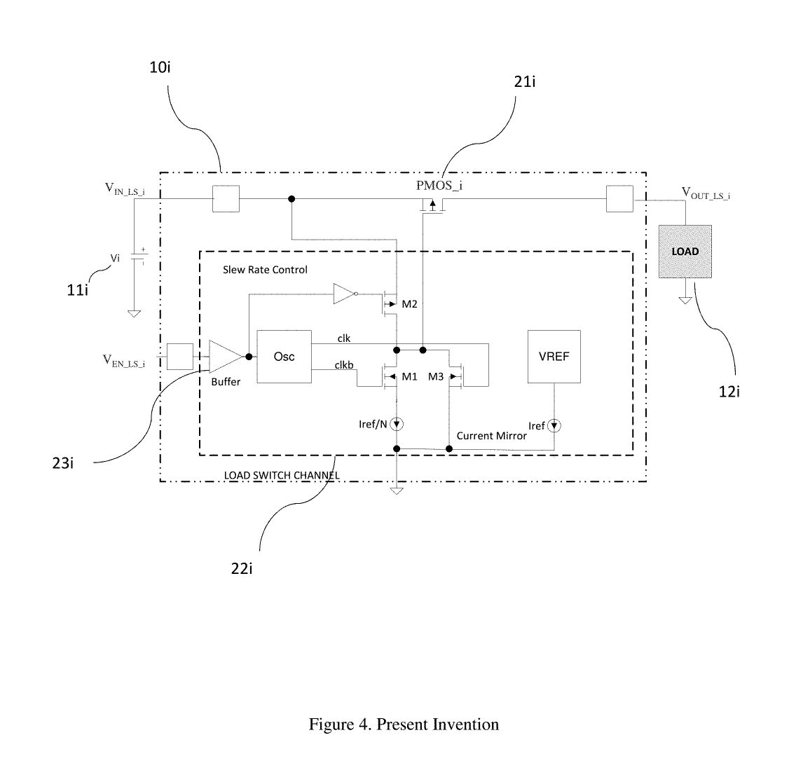

Another embodiment of the slew rate control circuit (SRCC_i) 22i is illustrated in the FIG. 4, which uses a chopped reference current where the chopping is delivered by an oscillator with a prescribed duty cycle in order to extend the turn on time of the power PMOS transistor (PMOS_i) 201 in excess of 30 ms.

It is noted that in adjusting the slew rate, that there can be adjustments as to both the amount of time that the voltage takes to rise, as well as the extent of the voltage rise. As such, the term “slew rate” is used in the art to refer to both the actual slew rate, as well as to the rise time, and is similarly used herein to mean both; with reference to the rise time being made when that is specifically being discussed.

The synchronization control circuit (SCC) 140 has:

a. one or more input(s) V_{EN}_{_}_{SCC}_{_}_{IN}_{_}ⱼ, wherein j is an integer lager than 0, and

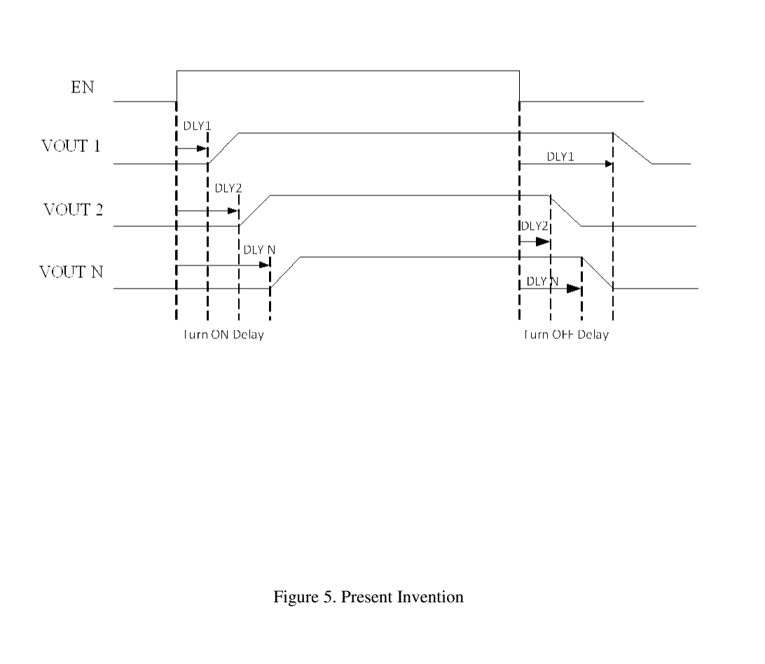

b. multiple outputs V_{EN}_{_}_{SCC}_{_}_{OUT}_{_}ᵢ, wherein i an integer larger than 1 but smaller than or equal to 2^{j} so that the input(s) V_{EN}_{_}_{SCC}_{_}_{IN}_{_}ⱼ can be programmed with their various combinations for individually selecting an LS_i. The V_{EN}_{_}_{SCC}_{_}_{OUT}_{_}ᵢ is/are connected to the V_{EN}_{_}_{LS}_{_}ᵢ. The FIG. 5 illustrates how the synchronization control circuit (SCC) 140 works. When the EN input signal V_{EN}_{_}_{SCC}_{_}_{IN}_{_}ⱼ is brought to a HIGH level, the sequencing of each of the load switches (LS_i) 10i begins. Each of the load switches (LS_i) is enabled after the prescribed delay and the rise time is then executed until the V_{OUT}_{_}_{LS}_{_}ᵢ level is equal to the V_{IN}_{_}_{LS}_{_}ᵢ level. When the EN input signal V_{EN}_{_}_{SCC}_{_}_{IN}_{_}ⱼ is brought to a low level, the OFF timing sequence is engaged. Thus the outputs are disabled in the prescribed sequence after executing the appropriate delay sequences.

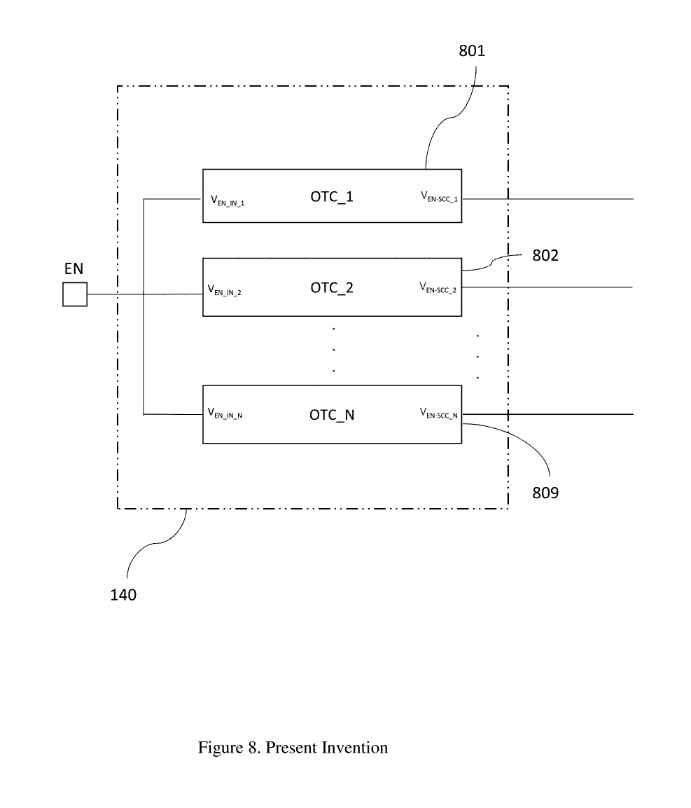

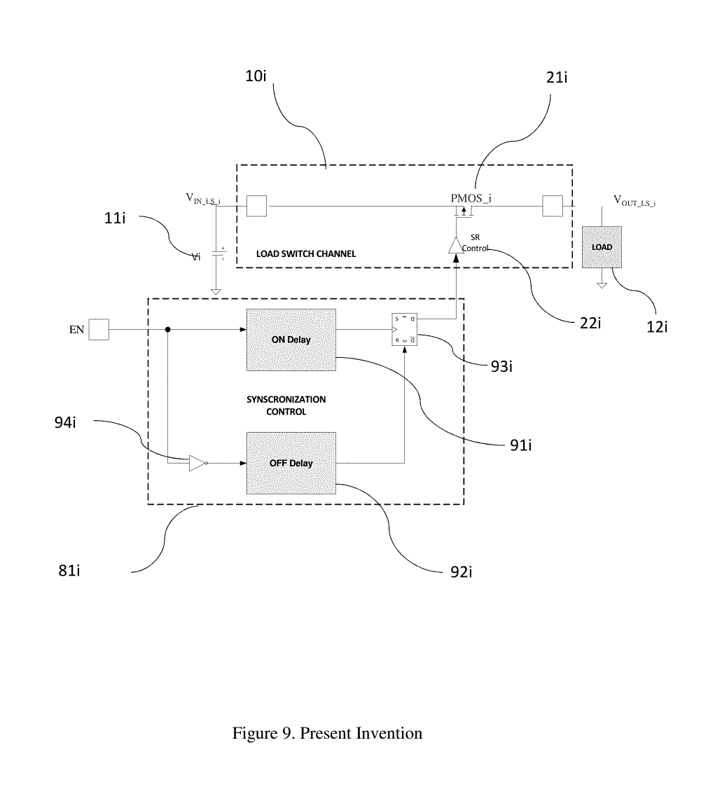

As shown in the FIG. 8, the synchronization control circuit (SCC) 140 has multiple independent ON/OFF-timing circuits (OTC_i) 81i. And as shown in the FIG. 9, each ON/OFF-timing circuit (OTC_i) 81i has an independent pair of ON Delay sequencing block/circuit (ON-DC_i) 91i and an OFF delay sequencing block/circuit (OFF-DC_i) 92i connected to a providing desired independently sequenced PMOS transistor (PMOS_i) 201 ON/OFF delay timing(s) relative to the input(s) V_{EN}_{_}_{SCC}_{_}_{IN}_{_}ⱼ, wherein j is an integer lager than 0.

The FIG. 9 is the basic block diagram of the switching circuit (SC) 100 for one of the load switches (LS_i) 10i. There is a load switch (LS_i) 10i and an ON/OFF timing circuit (OTC_i) 81i. There is an inverter 93i connected between EN and the OFF delay sequencing block/circuit (OFF-DC_i) 92i. The output of the ON Delay sequencing block/circuit (ON-DC_i) 91i is connected to the set of a latch 93i, and the output of the OFF delay sequencing block/circuit (OFF-DC_i) 92i is connected to the reset of the latch 93i. The slew rate control circuit (SRCC_i) 22i is enabled by the latch 93i after the prescribed ON delay sequencing block/circuit (ON-DC_i) 91i time out. Once the slew rate control is engaged, the latch 93i is set, and the load switch (LS_i) 10i is allowed to turn on and connect the V_{IN}_{_}_{LS}_{_}ᵢ pin to the V_{OUT}_{_}_{LS}_{_}ᵢ pin. Once the V_{EN}_{_}_{LS}_{_}ᵢ pin is brought to a logic LOW level, then the OFF delay is engaged. The OFF delay sequencing block/circuit (OFF-DC_i) 92i will time out and then reset the latch 93i causing the PMOS transistor (PMOS_i) 201 to be turned off, disconnecting the V_{OUT}_{_}_{LS}_{_}ᵢ pin from the V_{IN}_{_}_{LS}_{_}ᵢ pin.

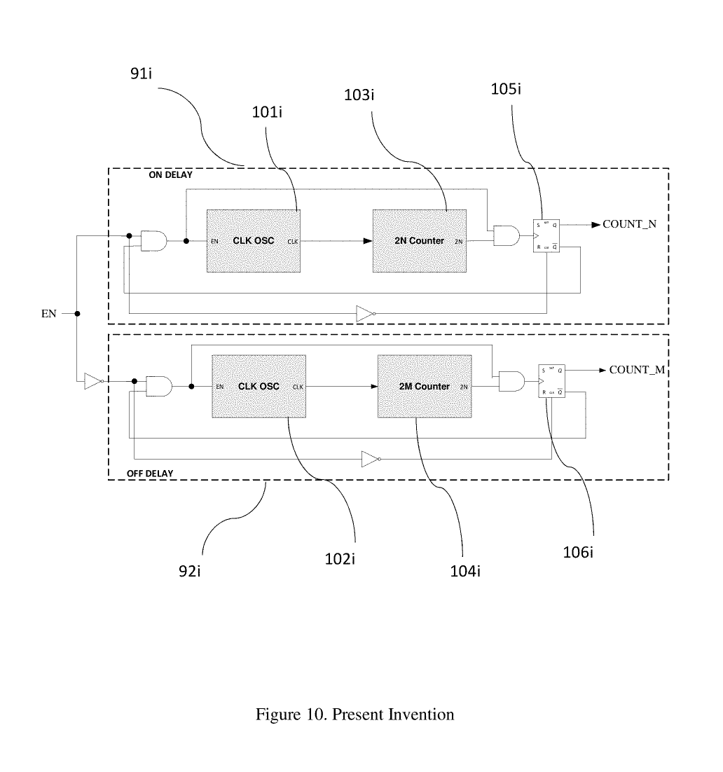

The FIG. 10 illustrates the details of the ON delay sequencing block/circuit (ON-DC_i) 91i or the OFF delay sequencing block/circuit (OFF-DC_i) 92i, and they are identically designed. Each delay counter ON-DC_i 91i/OFF-DC_i 92i consists of an oscillator 101i/102i and a 2^{N} counter 103i/104i along with some logic. When the V_{EN}_{_}_{LS}_{_}ᵢ pin is brought to a HIGH level, the oscillator 101i/102i is enabled and the 2^{N} counter 103i/104i begins to count clock cycles. Once the Nth count has been achieved, the 2^{N} output is brought HIGH and the latch 105i/106i is energized to clock its output HIGH. The COUNT output is then used to enable the slew rate control circuit (SRCC_i) 22i to turn on the load switches (LS_i). When the V_{EN}_{_}_{LS}_{_}ᵢ pin is brought LOW, then the oscillator 101i/102i is disabled and the 2^{N} counter 103i/104i and the latch 105i/106i are reset.

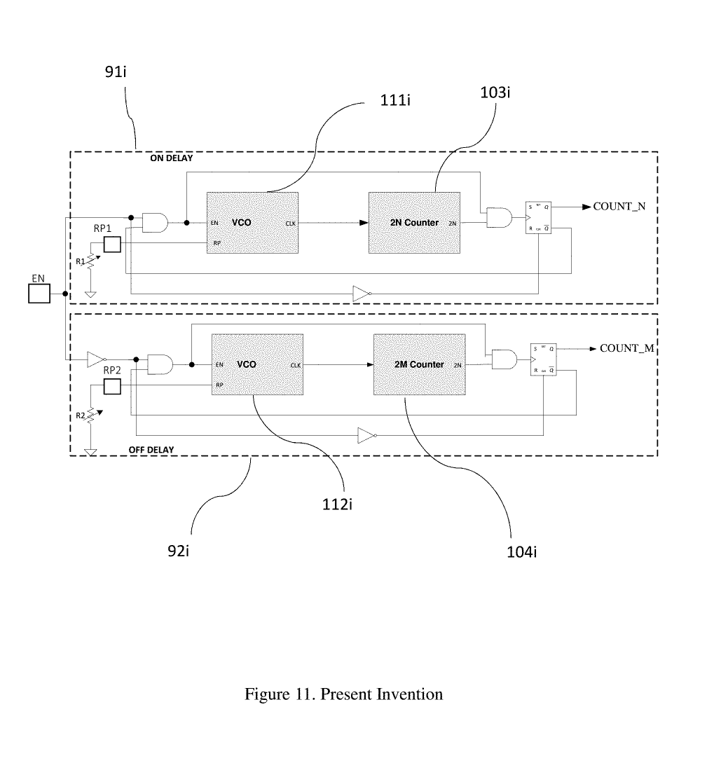

The FIG. 11 illustrates an embodiment of the ON delay sequencing block/circuit (ON-DC_i) 91i or the OFF delay sequencing block/circuit (OFF-DC_i) 92i. Each delay counter ON-DC_i/OFF-DC_i 90i/91i consists of the voltage controlled oscillator (VCO) 111i/112i and a 2^{N} counter 103i/104i along with some logic. When the EN pin is brought to a HIGH level, the voltage controlled oscillator (VCO) 111i/112i is enabled and the 2^{N} counter 103i/104i begins to count clock cycles. Once the Nth count has been achieved, the 2^{N} output is brought HIGH and the latch 105i/106i is energized to clock its output HIGH. The COUNT output is then used to enable the slew rate control system to turn on the load switch. When the EN pin is brought LOW, then the voltage controlled oscillator (VCO) 111i/112i is disabled and the 2^{N} counter 103i/104i and the latch 105i/106i are reset. For achieving an additional degree of flexibility for a user in adjusting ON delays, an extra input connected to an adjustable off-chip resistor for adjusting an input voltage of the voltage controlled oscillator (VCO) 111i/112i.

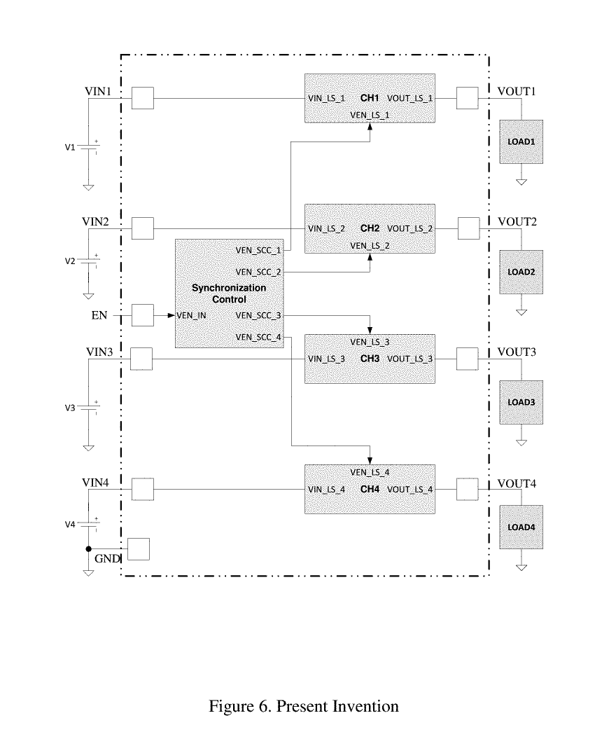

The FIG. 6 illustrates a specific embodiment of the invention with four load switches (LS_i) 10i. In this embodiment, each of the load switches (LS_i) 10i can be independently sequenced into the ON state by the synchronization control circuit (SSC) 140 similar to the sequencing shown in the FIG. 5.

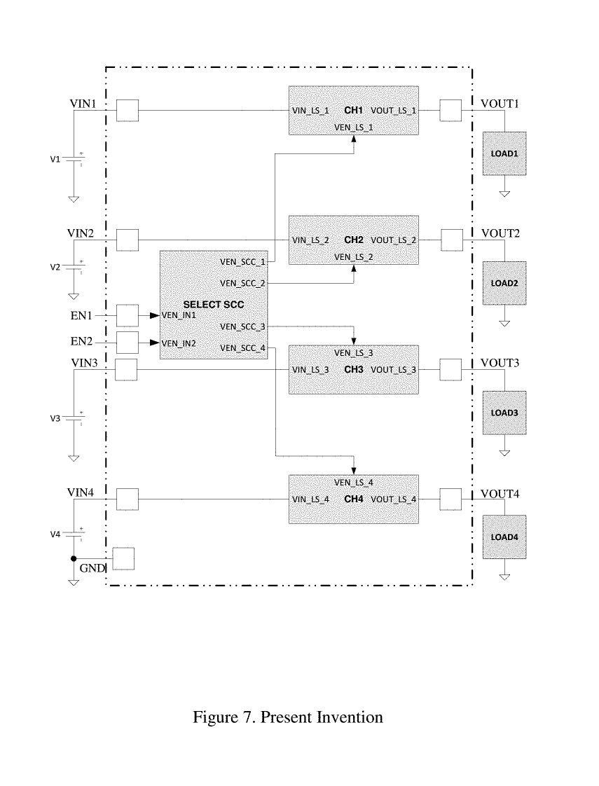

The FIG. 7 illustrates an embodiment of the invention with four load switches (LS_i) 10i. In this embodiment, the synchronizing controller (SSC) 140 is allowed to only enable one of the four channels at any one given time according to the input HIGH/LOW levels of the two enable input pins, EN1 and EN2.

What we claim is:

1. A switching circuit (SC), connectable between external multiple input voltage sources and external multiple output loads and capable of controlling inrush currents to the external multiple output loads upon turn-on, comprising:
a. multiple load switches LS_i, wherein i is an integer larger than 1; and
b. a synchronization control circuit (SCC) controlling the multiple load switches LS_i.

2. The SC of claim 1 wherein
a. the LS_i comprises a power input V_{IN}_{_}_{LS}_{_}ᵢ, a control input V_{EN}_{_}_{LS}_{_}ᵢ, a power output V_{OUT}_{_}_{LS}_{_}ᵢ;
b. the SCC comprises
i. one or more input(s) V_{EN}_{_}_{SCC}_{_}_{IN}_{_}ⱼ, wherein j is an integer lager than 0, and
ii. multiple outputs V_{EN}_{_}_{SCC}_{_}_{OUT}_{_}ᵢ, wherein i an integer larger than 1 but smaller than or equal to 2^{j} so that the input(s) V_{EN}_{_}_{SCC}_{_}_{IN}_{_}ⱼ can be programmed with their various combinations for individually selecting an LS_i; and
c. the V_{EN}_{_}_{SCC}_{_}_{OUT}_{_}ᵢ is/are connected to the V_{EN}_{_}_{LS}_{_}ᵢ.

3. The SC of claim 1 wherein each LS_i comprises
a. a PMOS transistor (PMOS_i) having its source and drain respectively connected to the power input V_{IN}_{_}_{LS}_{_}ᵢ and the power output V_{OUT}_{_}_{LS}_{_}ᵢ; and
b. a slew rate control circuit (SRCC_i) having its input connected to the output V_{EN}_{_}_{SCC}_{_}_{OUT}_{_}ᵢ of the SCC and having its output connected the PMOS_i gate.

4. The SC of claim 3 wherein the SRCC_i comprises a resistor controllable discharge current circuit for controlling a slew rate of a gate voltage on the PMOS_i for turning ON/OFF the PMOS_i.

5. The SC of claim 3 wherein the SRCC_i alternatively comprises a circuit having a current reference that is derived from a voltage reference source such as a bandgap reference and a current mirror circuit allowing the reference current to be divided by a ratio N in order to achieve a controlled slew rate rise time in excess of 1-2 ms for controlling a slew rate of a gate voltage on the PMOS_i for turning ON/OFF the PMOS_i.

6. The SC of claim 3 wherein the SRCC_i alternatively comprises a circuit having an oscillator that provides a clock signal to a current reference chopping circuit in order to control the slew rate voltage on the PMOS_i gate, wherein a duty cycle of the clock signal determines the ON time of the chopping circuit, for achieving a rise time of the slew rate control to be in excess of 30 ms.

7. The SC of claim 1 wherein the SCC comprises multiple independent ON/OFF-timing circuits (OTC_i) and each OTC_i comprises an independent pair of ON delay sequencing block/circuit (ON-DC_i) and an providing desired independently sequenced PMOS_i ON/OFF delay timing(s) relative to the input(s) V_{EN}_{_}_{SCC}_{_}_{IN}_{_}ⱼ, wherein j is an integer lager than 0.

8. The SC of claim 7 wherein the ON-DC_i comprises a clock oscillator and a programmable counter for generating the V_{EN}_{_}_{SCC}_{_}_{OUT}_{_}ᵢ having a desired PMOS_i gate ON delay timing relative to the V_{EN}_{_}_{SCC}_{_}_{IN}_{_}ⱼ.

9. The SC of claim 7 wherein the ON-DC_i alternatively comprises a voltage controlled oscillator (VCO), for achieving an additional degree of flexibility for a user in adjusting ON delays, and a programmable counter for generating the V_{EN}_{_}_{SCC}_{_}_{OUT}_{_}ᵢ having a desired PMOS_i gate ON delay timing relative to the V_{EN}_{_}_{SCC}_{_}_{IN}_{_}ⱼ.

10. The SC of claim 7 wherein the OFF-DC_i comprises a clock oscillator and a programmable counter for generating the V_{EN}_{_}_{SCC}_{_}_{OUT}_{_}ᵢ having a desired PMOS_i gate OFF delay timing relative to the V_{EN}_{_}_{SCC}_{_}_{IN}_{_}ⱼ.

11. The SC of claim 7 wherein the OFF-DC_i alternatively comprises a voltage controlled oscillator (VCO), for achieving an additional degree of flexibility for a user in adjusting OFF delays, and a programmable counter for generating the V_{EN}_{_}_{SCC}_{_}_{OUT}_{_}ᵢ having a desired PMOS_i gate OFF delay timing relative to the V_{EN}_{_}_{SCC}_{_}_{IN}_{_}ⱼ.

12. A method of providing a switching circuit (SC) connectable between external multiple input voltage sources and external multiple output loads and capable of controlling inrush currents to the external multiple output loads upon turn-on, comprising:
a. providing multiple load switches LS_i, wherein i is an integer larger than 1; and
b. providing a synchronization control circuit (SCC) controlling the multiple load switches LS_i.

13. The method of claim 12 wherein
a. providing the LS_i comprises providing a power input V_{IN}_{_}_{LS}_{_}ᵢ, a control input V_{EN}_{_}_{LS}_{_}ᵢ, a power output V_{OUT}_{_}_{LS}_{_}ᵢ;
b. providing the SCC comprises
i. providing one or more input(s) V_{EN}_{_}_{SCC}_{_}_{IN}_{_}ⱼ, wherein j is an integer lager than 0, and
ii. providing multiple outputs V_{EN}_{_}_{SCC}_{_}_{OUT}_{_}ᵢ, wherein i an integer larger than 1 but smaller than or equal to 2^{j} so that the input(s) V_{EN}_{_}_{SCC}_{_}_{IN}_{_}ⱼ can be programmed with their various combinations for individually selecting an LS_i; and
c. connecting the V_{EN}_{_}_{SCC}_{_}_{OUT}_{_}ᵢ to the V_{EN}_{_}_{LS}_{_}ᵢ.

14. The method of claim 12 wherein providing each LS_i comprises
a. providing a PMOS transistor (PMOS_i) having its source and drain respectively connected to the power input V_{IN}_{_}_{LS}_{_}ᵢ and the power output V_{OUT}_{_}_{LS}_{_}ᵢ; and
b. providing a slew rate control circuit (SRCC_i) having its input connected to the output V_{EN}_{_}_{SCC}_{_}_{OUT}_{_}ᵢ of the SCC and having its output connected the PMOS_i gate.

15. The method of claim 14 wherein providing the SRCC_i comprises providing a resistor controllable discharge current circuit for controlling a slew rate of a gate voltage on the PMOS_i for turning ON/OFF the PMOS_i.

16. The method of claim 14 wherein providing the SRCC_i alternatively comprises providing a circuit having a current reference that is derived from a voltage reference source such as a bandgap reference and a current mirror circuit allowing the reference current to be divided by a ratio N in order to achieve a controlled slew rate rise time in excess of 1-2 ms for controlling a slew rate of a gate voltage on the PMOS_i for turning ON/OFF the PMOS_i.

17. The method of claim 14 wherein providing the SRCC_i alternatively comprises providing a circuit having an oscillator that provides a clock signal to a current reference chopping circuit in order to control the slew rate voltage on the PMOS_i gate, wherein a duty cycle of the clock signal determines the ON time of the chopping circuit, for achieving a rise time of the slew rate control to be in excess of 30 ms.

18. The method of claim 12 wherein providing the SCC comprises providing multiple independent ON/OFF-timing circuits (OTC_i) and each OTC_i comprises providing an independent pair of ON Delay sequencing block/circuit (ON-DC_i) and an OFF delay sequencing block/circuit (OFF-DC_i) providing desired independently sequenced PMOS_i ON/OFF delay timing(s) relative to the input(s) V_{EN}_{_}_{SCC}_{_}_{IN}_{_}ⱼ, wherein j is an integer lager than 0.

19. The method of claim 18 wherein providing the ON-DC_i comprises providing a voltage controlled oscillator (VCO), for achieving an additional degree of flexibility for a user in adjusting ON delays, and a programmable counter for generating the V_{EN}_{_}_{SCC}_{_}_{OUT}_{_}ᵢ having a desired PMOS_i gate ON delay timing relative to the V_{EN}_{_}_{SCC}_{_}_{IN}_{_}ⱼ.

20. The method of claim 18 wherein providing the ON-DC_i alternatively comprises providing a voltage controlled oscillator (VCO), for achieving an additional degree of flexibility for a user in adjusting ON delays, and a programmable counter for generating the V_{EN}_{_}_{SCC}_{_}_{OUT}_{_}ᵢ having a desired PMOS_i gate ON delay timing relative to the V_{EN}_{_}_{SCC}_{_}_{IN}_{_}ⱼ.

21. The method of claim 18 wherein providing the OFF-DC_i comprises proving a clock oscillator and a programmable counter for generating the V_{EN}_{_}_{SCC}_{_}_{OUT}_{_}ᵢ having a desired PMOS_i gate OFF delay timing relative to the V_{EN}_{_}_{SCC}_{_}_{IN}_{_}ⱼ.

22. The method of claim 18 wherein providing the OFF-DC_i alternatively comprises a voltage controlled oscillator (VCO), for achieving an additional degree of flexibility for a user in adjusting OFF delays, and a programmable counter for generating the V_{EN}_{_}_{SCC}_{_}_{OUT}_{_}ᵢ having a desired PMOS_i gate OFF delay timing relative to the V_{EN}_{_}_{SCC}_{_}_{IN}_{_}ⱼ.
